(19) United States
(12) Patent Application Publication
(10) Pub. No.: US 2025/0234482 A1
(43) Pub. Date: Jul. 17, 2025

(54) THREE-DIMENSIONAL GAS-LIQUID DUAL PHASE HEAT DISSIPATION DEVICE

(71) Applicant: Auras Technology Co., Ltd., New Taipei City (TW)

(72) Inventors: Chie-Sheng LIM, New Taipei City (TW); Mu-Shu FAN, New Taipei City (TW); Chien-Chih SU, New Taipei City (TW); Hsing-Pao YU, New Taipei City (TW)

(21) Appl. No.: 18/937,244

(22) Filed: Nov. 5, 2024

Related U.S. Application Data
(60) Provisional application No. 63/620,018, filed on Jan. 11, 2024.

(30) Foreign Application Priority Data
Aug. 12, 2024 (TW) 113130091

(51) Int. Cl. H05K 7/20; G06F 1/20

(52) U.S. Cl. CPC H05K 7/20254; H05K 7/20163; H05K 7/20172; H05K 7/20272; H05K 7/20418; H05K 7/20472; G06F 1/20

(57) ABSTRACT

A three-dimensional gas-liquid dual phase heat dissipation device includes a vapor chamber module and a water-cooling head. The vapor chamber module includes a vapor chamber. The vapor chamber includes a first cover plate, a second cover plate and a side wall surrounding the first cover plate and the second cover plate to form a hollow chamber therein. The first cover plate is used to contact a heat source, and the water-cooling head is fixed on the second cover plate of the vapor chamber.

### RELATED APPLICATIONS

This application claims priorities to U.S. Provisional Application Ser. No. 63/620,018, filed Jan. 11, 2024 and Taiwan Application Serial Number 113130091, filed Aug. 12, 2024, the disclosures of which are incorporated herein by reference in their entireties.

### TECHNICAL FIELD

The present disclosure relates to a heat dissipation device. More particularly, the present disclosure relates to a three-dimensional gas-liquid dual phase heat dissipation device.

### BACKGROUND

With the advancement of technology, electronic products have become more popular, and gradually changed the life or work of many people. As the calculating power of the computers increases, the temperature control of the electronic components such as the central processing units and graphics chips is more important.

Electronic components such as the central processing units and graphics chips generate heat during operation and require proper cooling to achieve the best performance. In order to keep the central processing unit and graphics chips operating at a proper temperature, an appropriate three-dimensional gas-liquid dual phase heat dissipation device configuration may influence the performance of the electronic device.

In addition, when the appearance size of current electronic devices is getting smaller and the number of cores of the computing chip is increased, the heat generated by the computing chip is also increased.

Therefore, there is a need to improve the heat dissipation efficiency and reduce the operating temperature of the computing chip so as to improve the overall working efficiency of the electronic device.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide a three-dimensional gas-liquid dual phase heat dissipation device to improve the heat dissipation efficiency and further improve the overall working efficiency of the electronic device.

To achieve these and other advantages and in accordance with the objective of the embodiments of the present invention, as the embodiment broadly describes herein, the embodiments of the present invention provides a three-dimensional gas-liquid dual phase heat dissipation device including a vapor chamber module and a water-cooling head. The vapor chamber module includes a vapor chamber, and the vapor chamber includes a first cover plate, a second cover plate and a side wall surrounding the first cover plate and the second cover plate to form a hollow chamber therein, and the first cover plate is used to contact a heat source. The water-cooling head is fixed on the second cover plate of the vapor chamber.

In some embodiments, the vapor chamber module further includes a plurality of first heat pipes extending outward from the side wall of the vapor chamber.

In some embodiments, the vapor chamber module further includes a plurality of second heat pipes connecting to the second cover plate of the vapor chamber, and the second heat pipes is in fluid communication with the hollow chamber.

In some embodiments, each of the second heat pipes includes a connecting portion and a heat dissipation portion. The connecting portion is connected to the second cover plate of the vapor chamber, the heat dissipation portion is connected to the connecting portion, and the heat dissipation portion is parallel with the first heat pipes.

In some embodiments, the vapor chamber module further includes a heat dissipation fin module, and the first heat pipes and the second heat pipes penetrate into the heat dissipation fin module.

In some embodiments, the water-cooling head further includes a plurality of heat dissipation fins and a cover plate. The heat dissipation fins are formed on the second cover plate of the vapor chamber, the cooling liquid of the water-cooling head flows through the heat dissipation fins, and the cover plate is disposed on the heat dissipation fins.

In some embodiments, the water-cooling head further includes a fixing frame formed between the heat dissipation fins and the second cover plate of the vapor chamber.

In some embodiments, the three-dimensional gas-liquid dual phase heat dissipation device further includes a plurality of first fans equipped on the water-cooling head and the heat dissipation fin module.

In some embodiments, the three-dimensional gas-liquid dual phase heat dissipation device further includes a second fan equipped under the heat dissipation fin module.

In some embodiments, the three-dimensional gas-liquid dual phase heat dissipation device further includes a top cover and a back cover. The top cover includes a plurality of openings. In addition, the vapor chamber module and the water-cooling head are installed between the top cover and the back cover, and the first fans align with openings.

In some embodiments, the three-dimensional gas-liquid dual phase heat dissipation device further includes a heat dissipation radiator, a hot water pipe, and a cold water pipe. The hot water pipe is connected between the water-cooling head and the heat dissipation radiator, and the cold water pipe is connected between the water-cooling head and the heat dissipation radiator.

In some embodiments, the water-cooling head further includes a partition plate and an impeller. The partition plate is installed between the heat dissipation fins and the cover plate, and the impeller is equipped above the partition plate.

In some embodiments, the partition plate includes two water entrances and a water exit. The two water entrances are respectively disposed on two sides of the partition plate, and the water exit is located at a center of the partition plate and aligning with the impeller.

In some embodiments, the cover plate includes an arc depression, and the two ends of the arc depression are respectively aligned with the water entrances.

In some embodiments, the heat dissipation fins include a water collection groove.

In some embodiments, the water collection groove includes a long depression area and a central circular depression area. The long depression area passes through the heat dissipation fins and the central circular depression area is formed at a center of the long depression area to align with the water exit of the partition plate.

In some embodiments, the heat dissipation fins further include two baffle plates respectively disposed on outermost sides of the heat dissipation fins to guide the cooling liquid to flow to two ends of the heat dissipation fins.

Hence, the three-dimensional gas-liquid dual phase heat dissipation device disclosed in the present invention may utilize the vapor chamber to directly contact the heat source, and utilize the water-cooling head to directly reduce the working temperature of the vapor chamber. Therefore, the cooling liquid of the water-cooling head may directly contact the surface of the vapor chamber to effectively increase the heat dissipation efficiency of the heat dissipation device. In addition, the three-dimensional gas-liquid dual phase heat dissipation device may further utilize the heat pipes in fluid communication with the vapor chamber to increase the heat dissipation efficiency and the heat dissipation capacity of the three-dimensional gas-liquid dual phase heat dissipation device to reduce the working temperature of the computing chips so as to further improve the overall working efficiency of the electronic device.

### BRIEF DESCRIPTION OF THE DRAWINGS

The disclosure can be more fully understood by reading the following detailed description of the embodiment, with reference made to the accompanying drawings as follows:

FIG. 1 illustrates a schematic perspective view of a three-dimensional gas-liquid dual phase heat dissipation device according to one embodiment of the present invention;

FIG. 2 illustrates an exploded schematic diagram of partial elements of a three-dimensional gas-liquid dual phase heat dissipation device according to one embodiment of the present invention;

FIG. 3 illustrates a schematic perspective view of a vapor chamber and heat pipes connecting thereon of a three-dimensional gas-liquid dual phase heat dissipation device according to one embodiment of the present invention;

FIG. 4 illustrates an exploded schematic diagram of a water-cooling head of a three-dimensional gas-liquid dual phase heat dissipation device according to one embodiment of the present invention; and

FIG. 5 illustrates a schematic diagram of partial elements of the water-cooling head of the three-dimensional gas-liquid dual phase heat dissipation device of FIG. 4 from another angle.

### DETAILED DESCRIPTION OF THE PREFERRED EMBODIMENT

The following is a detailed description of the embodiments in conjunction with the accompanying drawings, but the provided embodiments are not intended to limit the scope of the disclosure, and the description of the structure and operation is not used to limit the execution sequence thereof. The structure of the recombination of components and the resulting devices with equal functions are all within the scope of this disclosure. In addition, the drawings are for illustration purposes only, and are not drawn according to the original scale. For ease of understanding, the same reference numbers are used in the drawings and the description to refer to the same or like parts.

In addition, the terms used in the entire description and the scope of the patent application, unless otherwise specified, usually have the usual meaning of each term used in this field, in the content disclosed here and in the special content. Some terms used to describe the disclosure are discussed below or elsewhere in this specification to provide additional guidance to those skilled in the art in the disclosure.

In the implementation mode and the scope of the present application, unless the article is specifically limited in the context, “a” and “the” can generally refer to a single or pluralities. In the steps, the numbering is only used to conveniently describe the steps, rather than to limit the sequence and implementation.

Secondly, the words “comprising”, “including”, “having”, “containing” and the like used in the present application are all open language, meaning including but not limited to.

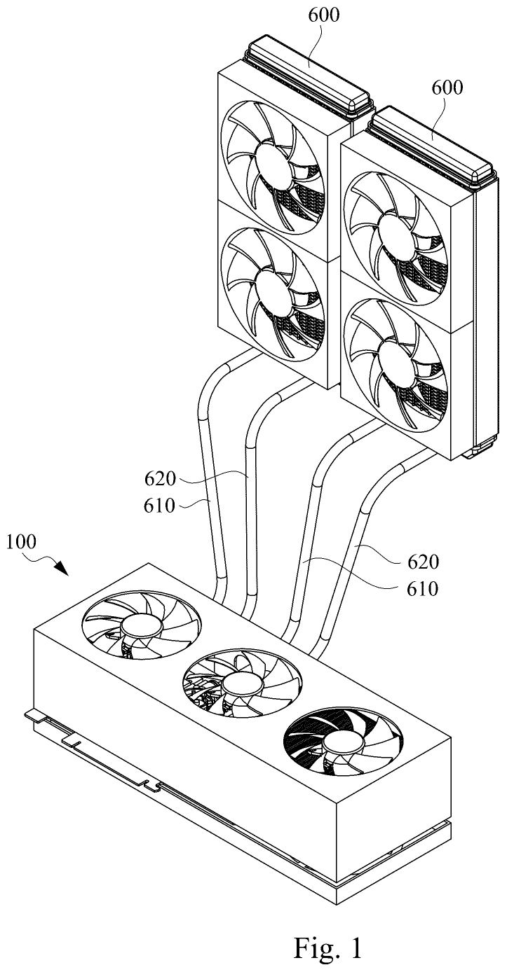

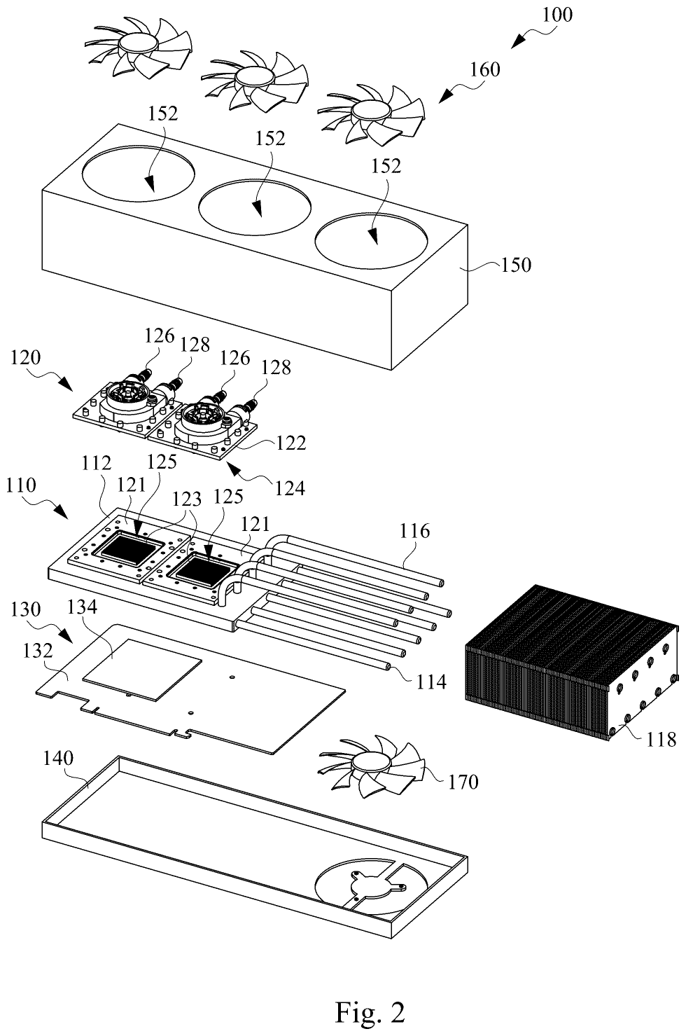

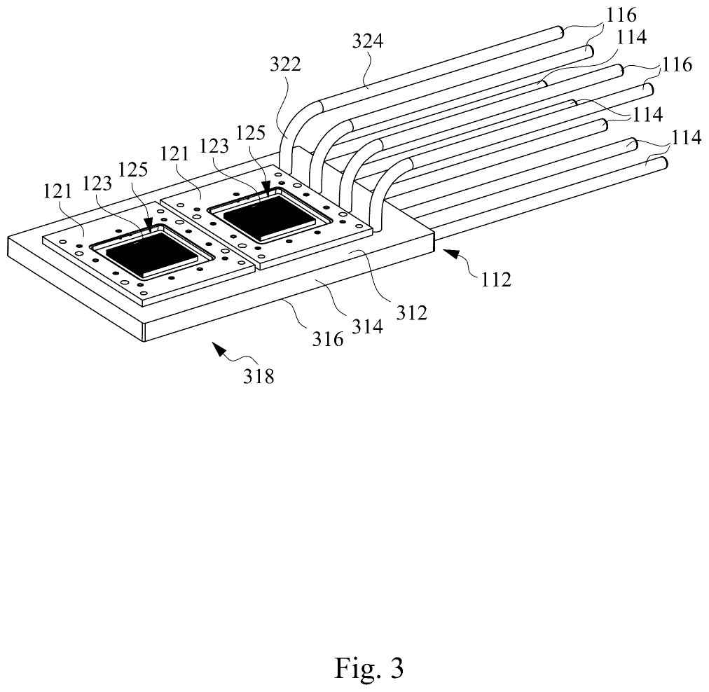

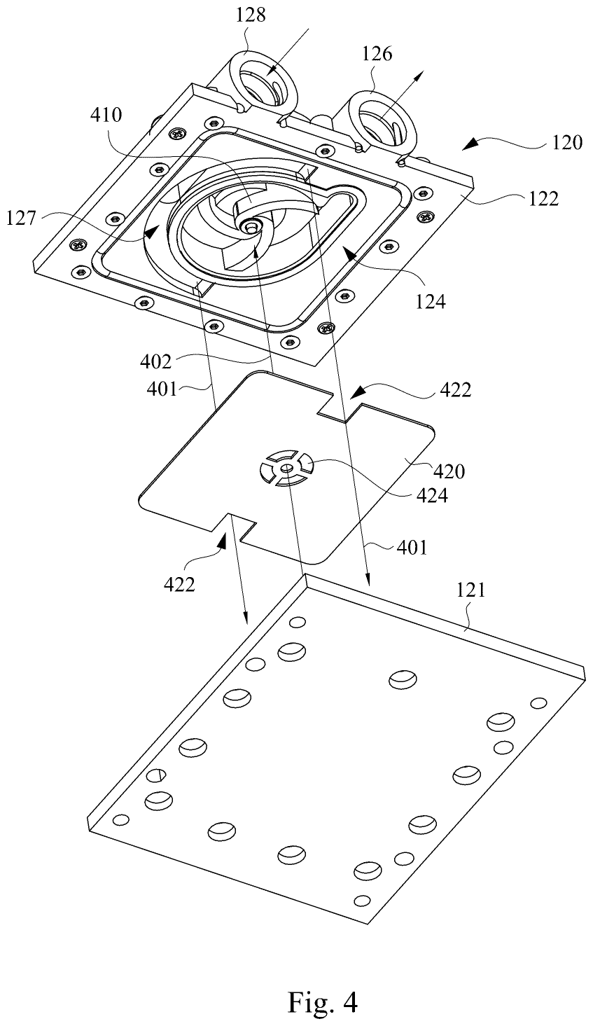

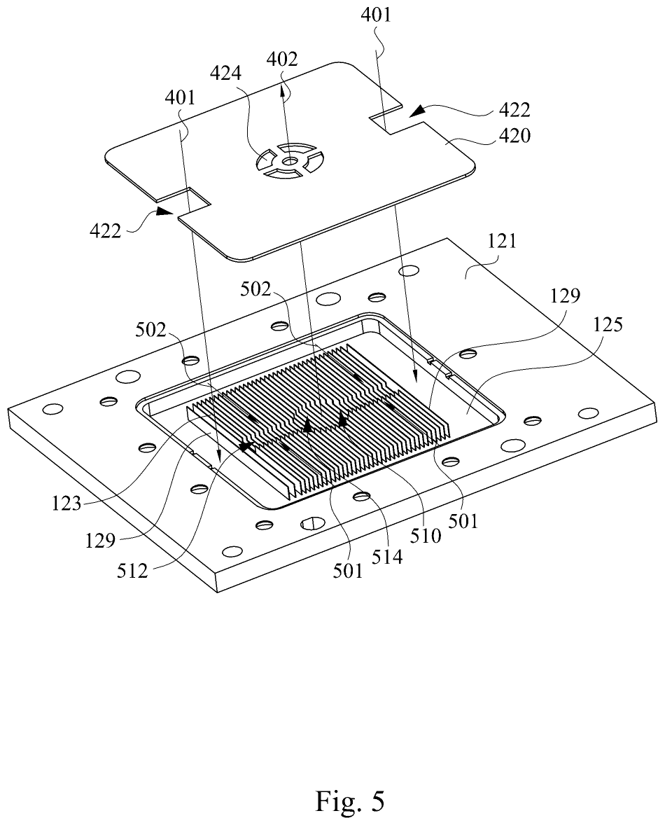

FIG. 1 is a schematic perspective view of a three-dimensional gas-liquid dual phase heat dissipation device according to one embodiment of the present invention, and FIG. 2 is an exploded schematic diagram of partial elements thereof. FIG. 3 is a schematic perspective view of a vapor chamber and heat pipes connecting on the vapor chamber of the three-dimensional gas-liquid dual phase heat dissipation device according to one embodiment of the present invention. In addition, FIG. 4 is an exploded schematic diagram of the water-cooling head of the three-dimensional gas-liquid dual phase heat dissipation device according to one embodiment of the present invention, and FIG. 5 is a schematic diagram of partial elements thereof from another angle.

Referring to FIG. 2 and FIG. 3, as shown in the drawings, the three-dimensional gas-liquid dual phase heat dissipation device 100 includes a vapor chamber module 110 and a water-cooling head 120. The vapor chamber module 110 includes a vapor chamber 112, and the vapor chamber 112 includes a first cover plate 316, a second cover plate 312 and a side wall 314. The side wall 314 surrounds between the first cover plate 316 and the second cover plate 312 to form a hollow chamber 318, and the first cover plate 316 is used to contact a heat source 134. The water-cooling head 120 is fixed on the second cover plate 312 of the vapor chamber 112.

In some embodiments, the heat source 134 may be a central processing unit chip, a graphics chip and/or any electronic component able to mount on a circuit board 132 to form an electronic device 130, for example, a motherboard, a graphics card or any other electronic device, without departing from the spirit and protection scope of the present invention.

In some embodiments, the side wall 314 preferably surrounds vertically between the first cover plate 316 and the second cover plate 312.

In addition, the first heat pipes 114 may be connected to the side wall 314 of the vapor chamber 112 and extend outward from the side wall 314 of the vapor chamber 112, and the first heat pipes 114 is in fluid communication with the hollow chamber 318.

In some embodiments, the first heat pipes 114 is connected to the side wall 314 of the vapor chamber 112 to horizontally extend outward from the side wall 314 of the vapor chamber 112.

In some embodiments, the first cover plate 316 is a heat-absorbing end metal plate, such as a copper metal plate, aluminum metal plate, stainless steel plate or any other metal plate to directly or indirectly contact a heat source 134. In addition, the second cover plate 312 is preferably a heat dissipation end metal plate, such as a copper metal plate, an aluminum metal plate, a stainless steel plate or any other metal plates to cool the heat dissipation fluid in the vapor chamber 112, but the present invention is not limited thereto.

In addition, it is worth noting that the cooling fluid in the vapor chamber 112 may be further guided to the outside of the vapor chamber 112 through the first heat pipes 114 from the hollow chamber 318 of the vapor chamber 112 to effectively increase the heat dissipation efficiency and cooling capability of the three-dimensional gas-liquid dual phase heat dissipation device 100.

In some embodiments, the three-dimensional gas-liquid dual phase heat dissipation device 100 may further include a second heat pipe 116 connected on the second cover plate 312 of the vapor chamber 112, and the second heat pipe 116 is in fluid communication with the hollow chamber 318.

In some embodiments, the second heat pipe 116 includes a connecting portion 322 and a heat dissipation portion 324. The connecting portion 322 is directly connected to the second cover plate 312 of the vapor chamber 112, and the heat dissipation portion 324 is connected to the connecting portion 322 and extends outward from the vapor chamber 112, for example, horizontally extending outward.

In some embodiments, the heat dissipation portion 324 is preferably parallel with the first heat pipe 114.

In some embodiments, the three-dimensional gas-liquid dual phase heat dissipation device 100 may further include a heat dissipation fin module 118, the heat dissipation fin module 118 is equipped outside the vapor chamber 112, and the heat dissipation portion 324 of the second heat pipe 116 and the first heat pipe 114 penetrate into the heat dissipation fin module 118. That is to say, the first heat pipe 114 extends outward from the side wall 314 of the vapor chamber 112 and is disposed in the heat dissipation fin module 118, and the second heat pipe 116 vertically extends outward from the second cover plate 312 of the vapor chamber 112 and then forms an angle of approximately 90 degrees so that the heat dissipation portion 324 of the second heat pipe 116 is also disposed in the heat dissipation fin module 118. Preferably, the heat dissipation portion 324 of the second heat pipe 116 is parallel with the first heat pipe 114 to increase the heat dissipation efficiency and cooling capability of the three-dimensional gas-liquid dual phase heat dissipation device 100.

Therefore, the first heat pipe 114 and the second heat pipe 116 of the three-dimensional gas-liquid dual phase heat dissipation device 100 are in fluid communication with the vapor chamber 112.

In some embodiments, the water-cooling head 120 further includes a fixing frame 121 and a plurality of heat dissipation fins 123. The fixing frame 121 is formed or fixed on the second cover plate 312 of the vapor chamber 112, and the heat dissipation fins 123 are formed on the fixing frame 121. In some embodiments, the fixing frame 121 includes a recessed cavity 125, and the heat dissipation fins 123 are formed in the recessed cavity 125 of the fixing frame 121. It is worth noting that a hollow depression 124 is formed under the cover plate 122 of the water-cooling head 120 and is in fluid communication with the hot water outlet 126 and the cold water inlet 128 so that the cooling liquid may enter into the hollow depression 124 under the cover plate 122 from the cold water inlet 128, pass through the heat dissipation fins 123 to cool the vapor chamber 112, and then flow out through the hot water outlet 126.

Simultaneously referring to FIGS. 1 and 2, in some embodiments, the three-dimensional gas-liquid dual phase heat dissipation device 100 further includes a heat dissipation radiator 600 connected to the hot water outlet 126 of the water-cooling head 120 with the hot water pipe 610, and connected to the cold water inlet 128 of the water-cooling head 120 with the cold water pipe 620 to further reduce the working temperature of the vapor chamber 112 with the heat dissipation radiator 600. Therefore, the cooling liquid is circulated in the heat dissipation radiator 600, the water-cooling head 120 and the vapor chamber 112 to reduce the working temperature of the heat source 134.

Referring to FIGS. 4 and 5, as shown in the drawings, the water-cooling head 120 further includes a partition plate 420 and an impeller 410, the partition plate 420 is equipped between the heat dissipation fins 123 and the cover plate 122, and the impeller 410 is equipped on one side of the partition plate 420, for example, above the partition plate 420. As the cooling liquid of the water-cooling head 120 enters into the arc depression 127 through the cold water inlet 128, the cooling liquid may flow to the two ends of the arc depression 127 along the arc depression 127, then pass through the water entrances 422 on two sides of the partition plate 420 along the arrow direction 401, enter into the two sides of the heat dissipation fins 123, for example, the two sides of the recessed cavity 125, respectively flow to the center of the heat dissipation fins 123 from the two sides of the heat dissipation fins 123 along the arrow direction 501 and the arrow direction 502 to take away the heat on the heat dissipation fins 123, be drawn by the impeller 410 to flow upward through the water exit 424 of the partition plate 420 along the arrow direction 402, and then discharge through the hot water outlet 126 of the water-cooling head 120.

In some embodiments, the heat dissipation fins 123 may further includes a water collection groove 510 formed in the center of the heat dissipation fins 123, and the water collection groove 510 includes a long depression area 512 passing through the center of the heat dissipation fins 123 and extending to two ends, and a central circular depression area 514 is formed at the center of the long depression area 512 and preferably aligned with the water exit 424 of the partition plate 420. The central circular depression area 514 is utilized to collect the cooling liquid to allow the cooling liquid to be drawn by the impeller 410 and flow upward through the water exit 424 of the partition plate 420 and then discharge through the hot water outlet 126 of the water-cooling head 120.

In some embodiments, the impeller 410 is aligned with the water exit 424 of the partition plate 420 and aligned with the central circular depression area 514.

In some embodiments, on the two sides of the heat dissipation fins 123, the heat dissipation fins 123 may further include baffle plates 129 respectively disposed on outermost sides of the heat dissipation fins 123 to guide the cooling liquid to flow to two ends of the heat dissipation fins 123, and then the cooling liquid may further flow to the center of the heat dissipation fins 123 along the arrow direction 501 and the arrow direction 502.

In some embodiments, the long depression area 512 are extended to the inner surfaces of the baffle plates 129 on two sides of the heat dissipation fins 123, but the present invention is not limited thereto.

In some embodiments, the three-dimensional gas-liquid dual phase heat dissipation device 100 may omit the fixing frame 121, and the heat dissipation fins 123 is integrally formed with the second cover plate 312 of the vapor chamber 112 or fixed on the second cover plate 312 of the vapor chamber 112. At this moment, the cover plate 122 of the water-cooling head 120 may directly seal on the surface of the second cover plate 312 to allow the cooling liquid not only flowing through the heat dissipation fins 123 but also flowing through the surface of the second cover plate 312 of the vapor chamber 112.

In some embodiments, the heat dissipation fins 123 and the baffle plate 129 may be directly formed or fixed on the surface of the second cover plate 312 of the vapor chamber 112, and the cover plate 122 of the water-cooling head 120 is directly sealed on the surface of the second cover plate 312 so that the partition plate 420 is disposed in the hollow depression 124 located above the heat dissipation fins 123 and under the cover plate 122 of the water-cooling head 120.

The present invention is not limited to this. The fixing frame 121 and the heat dissipation fins 123 may be formed separately from the second cover plate 312 of the vapor chamber 112, and then the fixing frame 121 and the heat dissipation fins 123 are fixed on the second cover plate 312 of the vapor chamber 112.

In addition, in some embodiments, the water-cooling head 120 may include independent cooling liquid circulations, and the water-cooling head 120 is fixed on the second cover plate 312 of the vapor chamber 112, without departing from the spirit and protection scope of the present invention.

In some embodiments, the heat dissipation fins 123 may be skived heat dissipation fins formed on the second cover plate 312 of the vapor chamber 112.

In some embodiments, the three-dimensional gas-liquid dual phase heat dissipation device 100 further includes a plurality of first fans 160 disposed above the water-cooling head 120 and the heat dissipation fin module 118 to increase the heat dissipation capacity of the three-dimensional gas-liquid dual phase heat dissipation device 100.

In some embodiments, the three-dimensional gas-liquid dual phase heat dissipation device 100 further includes a second fan 170, disposed under the heat dissipation fin module 118, to further increase the heat dissipation capacity of the three-dimensional gas-liquid dual phase heat dissipation device 100.

In some embodiments, the three-dimensional gas-liquid dual phase heat dissipation device 100 may further include a top cover 150 and a back cover 140. The top cover 150 may include a plurality of openings 152, and the vapor chamber module 110 and the water-cooling head 120 are disposed between the top cover 150 and the back cover 140. In addition, the first fans 160 are preferably aligned with the openings 152.

Accordingly, the three-dimensional gas-liquid dual phase heat dissipation device disclosed in the present invention may utilize the vapor chamber to directly contact the heat source, and utilize the water-cooling head to directly reduce the working temperature of the vapor chamber. Therefore, the cooling liquid of the water-cooling head may directly contact the surface of the vapor chamber to effectively increase the heat dissipation efficiency of the heat dissipation device. In addition, the three-dimensional gas-liquid dual phase heat dissipation device may further utilize the heat pipes in fluid communication with the vapor chamber to increase the heat dissipation efficiency and the heat dissipation capacity of the three-dimensional gas-liquid dual phase heat dissipation device to reduce the working temperature of the computing chips so as to further improve the overall working efficiency of the electronic device.

Although the present disclosure has been disclosed above in terms of implementation, it is not intended to limit the present disclosure. Any person with ordinary knowledge in the field may make various variations and modifications without departing from the spirit and scope of the disclosure. Therefore, the spirit and scope of the appended claims should not be limited to the description of the embodiments contained herein.

What is claimed is:

1. A three-dimensional gas-liquid dual phase heat dissipation device, comprising:
a vapor chamber module comprising a vapor chamber, wherein the vapor chamber comprises a first cover plate, a second cover plate and a side wall surrounding the first cover plate and the second cover plate to form a hollow chamber therein, and the first cover plate is used to contact a heat source; and
a water-cooling head fixed on the second cover plate of the vapor chamber.

2. The three-dimensional gas-liquid dual phase heat dissipation device according to claim 1, wherein the vapor chamber module further comprises:
a plurality of first heat pipes extending outward from the side wall of the vapor chamber.

3. The three-dimensional gas-liquid dual phase heat dissipation device according to claim 2, wherein the vapor chamber module further comprises:
a plurality of second heat pipes connecting to the second cover plate of the vapor chamber, and the second heat pipes is in fluid communication with the hollow chamber.

4. The three-dimensional gas-liquid dual phase heat dissipation device according to claim 3, wherein each of the second heat pipes comprises:
a connecting portion connecting to the second cover plate of the vapor chamber; and
a heat dissipation portion connecting to the connecting portion, and the heat dissipation portion is parallel with the first heat pipes.

5. The three-dimensional gas-liquid dual phase heat dissipation device according to claim 4, wherein the vapor chamber module further comprises:
a heat dissipation fin module, wherein the first heat pipes and the second heat pipes penetrate into the heat dissipation fin module.

6. The three-dimensional gas-liquid dual phase heat dissipation device according to claim 5, wherein the water-cooling head further comprises:
a plurality of heat dissipation fins formed on the second cover plate of the vapor chamber, and the cooling liquid of the water-cooling head flows through the heat dissipation fins; and
a cover plate disposed on the heat dissipation fins.

7. The three-dimensional gas-liquid dual phase heat dissipation device according to claim 6, wherein the water-cooling head further comprises:
a fixing frame formed between the heat dissipation fins and the second cover plate of the vapor chamber.

8. The three-dimensional gas-liquid dual phase heat dissipation device according to claim 7, further comprising:
a plurality of first fans equipped on the water-cooling head and the heat dissipation fin module.

9. The three-dimensional gas-liquid dual phase heat dissipation device according to claim 8, further comprising:
a second fan equipped under the heat dissipation fin module.

10. The three-dimensional gas-liquid dual phase heat dissipation device according to claim 9, further comprising:
a top cover comprising a plurality of openings; and
a back cover, wherein the vapor chamber module and the water-cooling head are installed between the top cover and the back cover, and the first fans align with openings.

11. The three-dimensional gas-liquid dual phase heat dissipation device according to claim 1, further comprising:
a heat dissipation radiator;
a hot water pipe connecting between the water-cooling head and the heat dissipation radiator; and
a cold water pipe connecting between the water-cooling head and the heat dissipation radiator.

12. The three-dimensional gas-liquid dual phase heat dissipation device according to claim 6, wherein the water-cooling head further comprises:
a partition plate installed between the heat dissipation fins and the cover plate; and
an impeller equipped above the partition plate.

13. The three-dimensional gas-liquid dual phase heat dissipation device according to claim 12, wherein the partition plate comprises:
two water entrances respectively disposed on two sides of the partition plate; and
a water exit located at a center of the partition plate and aligning with the impeller.

14. The three-dimensional gas-liquid dual phase heat dissipation device according to claim 13, wherein the cover plate comprises an arc depression, and the two ends of the arc depression are respectively aligned with the water entrances.

15. The three-dimensional gas-liquid dual phase heat dissipation device according to claim 14, wherein the heat dissipation fins comprise a water collection groove.

16. The three-dimensional gas-liquid dual phase heat dissipation device according to claim 15, wherein the water collection groove comprises:
a long depression area passing through the heat dissipation fins; and
a central circular depression area formed at a center of the long depression area to align with the water exit of the partition plate.

17. The three-dimensional gas-liquid dual phase heat dissipation device according to claim 16, wherein the heat dissipation fins further comprise:
two baffle plates respectively disposed on outermost sides of the heat dissipation fins to guide the cooling liquid to flow to two ends of the heat dissipation fins.
